(19) United States
(12) Patent Application Publication
(10) Pub. No.: US 2025/0176372 A1
(43) Pub. Date: May 29, 2025

(54) DISPLAY DEVICE

(71) Applicant: LG Display Co., Ltd., Seoul (KR)

(72) Inventors: Mingeun SONG, Paju-si (KR); JongWoo PARK, Paju-si (KR); JiHyun ROH, Paju-si (KR)

(73) Assignee: LG Display Co., Ltd., Seoul (KR)

(21) Appl. No.: 18/765,090

(22) Filed: Jul. 5, 2024

(30) Foreign Application Priority Data
Nov. 23, 2023 (KR) 10-2023-0164069

(51) Int. Cl. H10K 59/123; H10K 59/122; H10K 59/40; H10K 59/80

(52) U.S. Cl. CPC H10K 59/123; H10K 59/122; H10K 59/40; H10K 59/80515

(57) ABSTRACT

A display device can include a substrate, a tilt electrode disposed on the substrate and having an upper surface of a tilting slope, a pixel electrode disposed to overlap the tilt electrode, a light emitting layer disposed to overlap the pixel electrode, and a cathode electrode disposed to overlap the light emitting layer, thereby increasing the viewing angle of the display device.

### CROSS-REFERENCE TO RELATED APPLICATION

This application claims priority to Korean Patent Application No. 10-2023-0164069, filed in the Republic of Korea on Nov. 23, 2023, the entire contents of which is hereby expressly incorporated by reference into the present application.

### BACKGROUND

### Field

Embodiments of the present disclosure relate to a display device.

### Discussion of the Related Art

Nowadays, demand for display devices for displaying information, images, videos and messages is increasing in various forms. Recently, various display devices such as liquid crystal displays and organic light emitting display devices have been used to portably display various information, images, videos and messages.

In the case of an organic light emitting display device, a top emission method in which light is emitted in an opposite direction of a substrate can be adopted to achieve a high aperture ratio and a flexible circuit configuration on the substrate.

In related top emission display devices, there was a problem with the viewing angle becoming narrow due to resonance of light.

### SUMMARY OF THE DISCLOSURE

Embodiments of the present disclosure can provide a display device with a wider viewing angle.

Embodiments of the present disclosure can provide a display device capable of increasing frontal brightness.

Embodiments of the present disclosure can provide a display device capable of low power consumption with improved viewing angle characteristics.

Embodiments of the present disclosure can provide a display device including a substrate, a tilt electrode disposed on the substrate and disposed to have an upper surface of a tilting slope, a pixel electrode disposed to overlap the tilt electrode, a light emitting layer disposed to overlap the pixel electrode, and a cathode electrode disposed to overlap the light emitting layer.

A display device according to embodiments of the present disclosure can further include an organic film planarization layer disposed between the tilt electrode and the pixel electrode and including a contact hole, wherein the tilt electrode can contact the pixel electrode through the contact hole in the organic film planarization layer.

A display device according to embodiments of the present disclosure can further include a driving transistor disposed between the substrate and the tilt electrode, wherein the tilt electrode can be an electrode included in the driving transistor or a pattern electrically connected to the driving transistor.

The organic film planarization layer can be disposed to have a slope less than or equal to the tilting slope in an area overlapping with the tilt electrode. The pixel electrode can be disposed to have a slope less than or equal to the tilting slope in an area overlapping with the tilt electrode. The light emitting layer can be disposed to have a slope less than or equal to the tilting slope in an area overlapping with the tilt electrode, and the cathode electrode can be disposed to have a slope less than or equal to the tilting slope in an area overlapping with the tilt electrode.

The substrate can include a normal subpixel and an inclined subpixel. A tilt electrode of the normal subpixel can be arranged to be flat, and a tilt electrode of the inclined subpixel can be arranged to have a slope less than or equal to the tilting slope.

According to embodiments of the present disclosure, it is possible to provide a display device with wider viewing angle.

According to embodiments of the present disclosure, it is possible to provide a display device capable of increasing frontal brightness.

According to embodiments of the present disclosure, it is possible to provide a display device capable of low power consumption with improved viewing angle characteristics.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a diagram schematically illustrating a configuration of a display device according to embodiments of the present disclosure.

FIG. 2 is a cross-sectional view of a light emitting area in a display panel area.

FIG. 3 is a cross-sectional view of a light emitting device according to embodiments of the present disclosure.

FIG. 4 is a graph representing an ideal viewing angle and a reduced viewing angle due to the micro cavity effect.

FIG. 5 is a cross-sectional view of a light emitting area in a display panel area according to embodiments of the present disclosure.

FIG. 6 is a diagram illustrating a method of arranging red subpixels of a display panel according to embodiments of the present disclosure.

FIG. 7 is a diagram illustrating a red subpixel according to embodiments of the present disclosure.

FIG. 8 is a diagram illustrating a method of arranging green subpixels of a display panel according to embodiments of the present disclosure.

FIG. 9 is a diagram illustrating a green subpixel according to embodiments of the present disclosure.

FIG. 10 is a diagram illustrating a method of arranging blue subpixels of a display panel according to embodiments of the present disclosure.

FIG. 11 is a diagram illustrating a blue subpixel according to embodiments of the present disclosure.

FIG. 12 is a diagram of a display panel having the divided areas according to embodiments of the present disclosure.

FIG. 13 is a cross-sectional view of a light emitting area in a left area of the display panel of FIG. 12 according to embodiments of the present disclosure.

FIG. 14 is a cross-sectional view of a light emitting area in a right area of the display panel of FIG. 12 according to embodiments of the present disclosure.

FIG. 15 is a cross-sectional view of light emitting areas of a display panel divided into areas according to embodiments of the present disclosure.

FIG. 16 is a diagram of a display panel according to embodiments of the present disclosure.

FIG. 17 is a diagram of an edge area of a display panel according to embodiments of the present disclosure.

FIGS. 18 and 19 are diagrams of edge areas of a display panel according to embodiments of the present disclosure.

FIGS. 20 and 21 are diagrams of display panels according to embodiments of the present disclosure.

### DETAILED DESCRIPTION OF THE EMBODIMENTS

Hereinafter, embodiments of the disclosure are described in detail with reference to the accompanying drawings. In assigning reference numerals to components of each drawing, the same components can be assigned the same numerals even when they are shown on different drawings. When it is determined that a detailed description of the subject matter of the disclosure is obscured by discussion of known art or functions, the detailed description of the known art or functions can be skipped. As used herein, when a component “includes,” “has,” or “is composed of” another component, the component can further include other components unless the component is described in terms of “only” includes, has, or “is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” can be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components can be directly “connected”, “coupled” or “linked”, or another component can intervene. Here, the other component can be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it can include a non-continuous relationship unless the term “immediately” or “directly” is used.

When a component is designated with a value or its corresponding information (e.g., level), the value or the corresponding information can be interpreted as including a tolerance that can arise due to various factors (e.g., process factors, internal or external impacts, or noise).

The term “can” fully encompass all the meanings and coverages of the term “may.”

Hereinafter, various embodiments of the disclosure are described in detail with reference to the accompanying drawings.

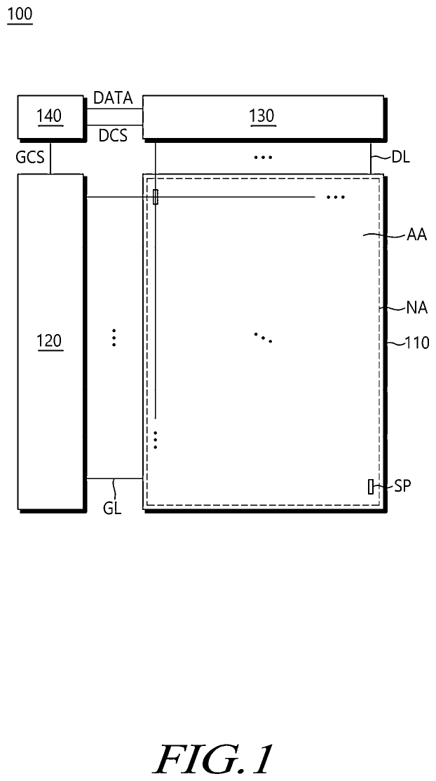

FIG. 1 is a diagram schematically illustrating a configuration of a display device 100 according to embodiments of the present disclosure. All the components of the display device according to all embodiments are operationally coupled and configured.

Referring to FIG. 1, a touch display device 100 can include a display panel 110, a gate driving circuit 120, a data driving circuit 130, and a controller 140 for driving the display panel 110. The touch display device 100 can further include a component for touch sensing in addition to a component for display driving. But embodiments of the present disclosure are limited thereto.

The display panel 110 can include an active area AA in which a plurality of subpixels SP are disposed, and a non-active area NA located outside the active area AA. A plurality of gate lines GL and a plurality of data lines DL can be disposed on the display panel 110. A plurality of subpixels SP can be located in an area where the gate line GL and the data line DL intersect.

The gate driving circuit 120 can be controlled by the controller 140. The gate driving circuit 120 can sequentially output scan signals to the plurality of gate lines GL disposed on the display panel 110 to control the driving timing of the plurality of subpixels SP.

The gate driving circuit 120 can include one or more gate driver integrated circuits (GDIC). The gate driving circuit 120 can be located on only one side or both sides of the display panel 110 depending on the driving method.

Each gate driver integrated circuit (GDIC) can be connected to a bonding pad of the display panel 110 using a tape automated bonding (TAB) method or a chip on glass (COG) method. Alternatively, each gate driver integrated circuit (GDIC) can be implemented as a gate-in-panel (GIP) type and placed directly on the display panel 110. Alternatively, each gate driver integrated circuit (GDIC) can be integrated and disposed on the display panel 110. Alternatively, each gate driver integrated circuit (GDIC) can be implemented using a chip on film (COF) method mounted on a film connected to the display panel 110. But embodiments of the present disclosure are limited thereto.

The data driving circuit 130 can receive image data DATA from the controller 140 and convert the image data DATA into an analog data voltage Vdata. The data driving circuit 130 can output a data voltage Vdata to each data line DL in accordance with the timing at which the scan signal is applied through the gate line GL, so that each subpixel can express brightness according to the image data DATA.

The data driving circuit 130 can include one or more source driver integrated circuits (SDIC). Each source driver integrated circuit (SDIC) can include a shift register, a latch circuit, a digital-to-analog converter, and an output buffer. But embodiments of the present disclosure are limited thereto.

Each source driver integrated circuit (SDIC) can be connected to a bonding pad of the display panel 110 using a tape automated bonding (TAB) method or a chip on glass (COG) method. Alternatively, each source driver integrated circuit (SDIC) can be directly disposed on the display panel 110. Alternatively, each source driver integrated circuit (SDIC) can be integrated and disposed on the display panel 110. Alternatively, each source driver integrated circuit (SDIC) can be implemented in a chip on film (COF) method. In this case, each source driver integrated circuit (SDIC) can be mounted on a film connected to the display panel 110 and electrically connected to the display panel 110 through lines on the film.

The controller 140 can supply various control signals to the gate driving circuit 120 and the data driving circuit 130, and control the operation of the gate driving circuit 120 and the data driving circuit 130.

The controller 140 can be mounted on a printed circuit board (SUB) or flexible printed circuit. The controller 140 can be electrically connected to the gate driving circuit 120 and the data driving circuit 130 through a printed circuit board (SUB) or a flexible printed circuit. The printed circuit board can also be referred to as a PCB.

The controller 140 can control the gate driving circuit 120 to output a scan signal according to the timing set in each frame. The controller 140 can convert image data received from an external source (e.g., host system) to the data signal format used in the data driving circuit 130, and can output converted image data DATA to the data driving circuit 130.

The controller 140 can receive various timing signals including vertical synchronization signal VSYNC, horizontal synchronization signal HSYNC, input data enable signal DE, and clock signal CLK along with image data DATA from an external source (e.g., a host system).

The controller 140 can generate various control signals using various timing signals received from the outside, and output the control signals to the gate driving circuit 120 and the data driving circuit 130.

As an example, in order to control the gate driving circuit 120, the controller 140 can output various gate control signals GCS including a gate start pulse, a gate shift clock GSC and a gate output enable signal GOE to the gate driving circuit 120.

The gate start pulse GSP can control the operation start timing of one or more gate driver integrated circuits (GDIC) constituting the gate driving circuit 120. The gate shift clock GSC can be a clock signal commonly input to one or more gate driver integrated circuits (GDIC), and can control the shift timing of the scan signal. The gate output enable signal GOE can specify timing information of one or more gate driver integrated circuits (GDIC).

In addition, in order to control the data driving circuit 130, the controller 140 can output Various data control signals DCS including a source start pulse SSP, a source sampling clock SSC and a source output enable signal SOE to the data driving circuit 130.

The source start pulse SSP can control the data sampling start timing of one or more source driver integrated circuits (SDICs) constituting the data driving circuit 130. The source sampling clock SSC can be a clock signal for controlling sampling timing of data in each of one or more source driver integrated circuits (SDICs). The source output enable signal SOE can control the output timing of the data driving circuit 130.

The touch display device 100 can supply various voltages or currents to the display panel 110, the gate driving circuit 120, and the data driving circuit 130, or can further include a power management integrated circuit which controls various voltages or currents to be supplied.

Each subpixel SP can be an area defined by the intersection of the gate line GL and the data line DL, and a liquid crystal layer or a light emitting device can be disposed depending on the type of the touch display device 100.

For example, if the touch display device 100 is an organic light emitting display device 100, organic light emitting diodes (OLEDs) and various circuit elements can be disposed in a plurality of subpixels SP. Each subpixel SP can display brightness corresponding to image data by controlling the current supplied to the organic light emitting diode (OLED) by various circuit elements. But embodiments of the present disclosure are limited thereto.

Alternatively, in some cases, a light emitting diode (LED), micro light emitting diode (μLED), or quantum dot light emitting diode (QLED) can be disposed in the subpixel SP. But embodiments of the present disclosure are limited thereto.

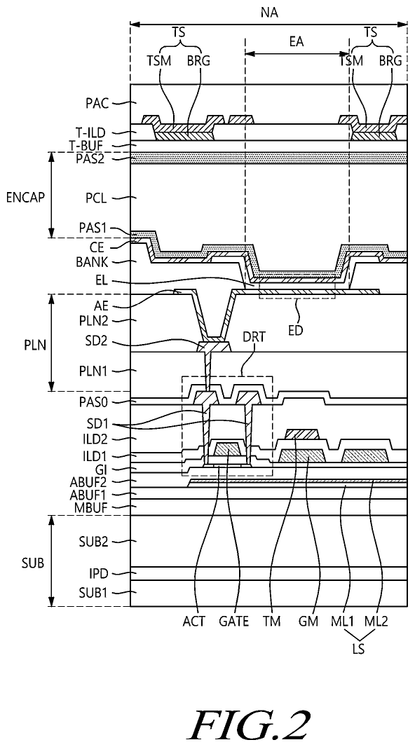

FIG. 2 is a cross-sectional view of a normal area NA included in the active area AA of the display panel 110 according to embodiments of the present disclosure.

In the display panel 110 shown in FIG. 1, a touch sensor TS can be present inside the display panel 110, and FIG. 2 is a cross-sectional view of the display panel 110 when the touch sensor TS is present inside the display panel 110.

However, FIGS. 1 and 2 are simply drawings of an example of the display panel 110 including the touch sensor TS, and the present disclosure is not limited to a display panel 110 including the touch sensor TS.

Referring to FIG. 2, a substrate SUB can include a first substrate SUB1, an interlayer insulating film IPD, and a second substrate SUB2. But embodiments of the present disclosure are limited thereto. The interlayer insulating film IPD can be located between the first substrate SUB1 and the second substrate SUB2. Moisture penetration can be prevented by composing the substrate SUB with a first substrate SUB1, an interlayer insulating film IPD, and a second substrate SUB2. But embodiments of the present disclosure are limited thereto. For example, the first substrate SUB1 and the second substrate SUB2 can be polyimide (PI) substrates. The first substrate SUB1 can be referred to as a primary PI substrate, and the second substrate SUB2 can be referred to as a secondary PI substrate.

Referring to FIG. 2, there can be disposed various patterns (ACT, SD1, GATE), various insulating films (MBUF, ABUF1, ABUF2, GI, ILD1, ILD2, PAS0), and various metal patterns (TM, GM, ML1, ML2) on the substrate SUB. But embodiments of the present disclosure are limited thereto.

Referring to FIG. 2, a multi-buffer layer MBUF can be disposed on the second substrate SUB2, and a first active buffer layer ABUF1 can be disposed on the multi-buffer layer MBUF.

A first metal layer ML1 and a second metal layer ML2 can be disposed on the first active buffer layer ABUF1. Here, the first metal layer ML1 and the second metal layer ML2 can be a light shield layer LS which shields light.

A gate insulating film GI can be disposed while covering the active layer ACT.

A gate electrode GATE of a driving transistor DRT can be disposed on the gate insulating film GI. In this case, a gate material layer GM can be disposed on the gate insulating film GI along with the gate electrode GATE of the driving transistor DRT at a position different from the formation position of the driving transistor DRT.

A first interlayer insulating film ILD1 can be disposed covering the gate electrode GATE and the gate material layer GM. A metal pattern TM can be disposed on the first interlayer insulating film ILD1. The metal pattern TM can be located at a location different from the formation location of the driving transistor DRT. A second interlayer insulating film ILD2 can be disposed while covering the metal pattern TM on the first interlayer insulating film ILD1.

Two first source-drain electrode patterns SD1 can be disposed on the second interlayer insulating film ILD2. One of the two first source-drain electrode patterns SD1 can be a source node of the driving transistor (DRT), and the other can be a drain node of the driving transistor DRT.

The two first source-drain electrode patterns SD1 can be electrically connected to one side and the other side of the active layer ACT through the contact holes in the second interlayer insulating film ILD2, the first interlayer insulating film ILD1 and the gate insulating film GI.

The part of the active layer ACT which overlaps with the gate electrode GATE can be is a channel area. One of the two first source-drain electrode patterns SD1 can be connected to one side of the channel area in the active layer ACT, and the other one of the two first source-drain electrode patterns SD1 can be connected to the other side of the channel area in the active layer ACT.

A passivation layer PAS0 can be disposed while covering the two first source-drain electrode patterns SD1. A planarization layer PLN can be disposed on the passivation layer PAS0. The planarization layer PLN can include a first planarization layer PLN1 and a second planarization layer PLN2.

The first planarization layer PLN1 can be disposed on the passivation layer PAS0.

A second source-drain electrode pattern SD2 can be disposed on the first planarization layer PLN1. The second source-drain electrode pattern SD2 can be connected to one of the two first source-drain electrode patterns SD1 (corresponding to a second node Ny of the driving transistor DRT in the subpixel SP in FIG. 2) through a contact hole of the first planarization layer PLN1.

The second planarization layer PLN2 can be disposed while covering the second source-drain electrode pattern SD2. A light emitting device ED can be disposed on the second planarization layer PLN2.

As an example of a stacked structure of the light emitting device ED, an anode electrode AE can be disposed on the second planarization layer PLN2. The anode electrode AE can be electrically connected to the second source-drain electrode pattern SD2 through a contact hole in the second planarization layer PLN2.

A bank BANK can be disposed while covering a portion of the anode electrode AE. A portion of the bank BANK corresponding to a light emitting area or an emission area EA of the subpixel SP can be open.

A part of the anode electrode AE can be exposed through the opening (i.e., open portion) of the bank BANK. The light emitting layer 307 (EL) of the light emitting device ED can be located on the side of the bank BANK and the opening (i.e., open portion) of the bank BANK. All or part of the light emitting layer 307 (EL) can be located between adjacent banks BANK.

At the opening of the bank BANK, the light emitting layer 307 (EL) can contact the anode electrode AE. A cathode electrode CE can be disposed on the light emitting layer 307 (EL).

A light emitting device ED can be formed by the anode electrode AE, the light emitting layer 307 (EL), and the cathode electrode CE. The light emitting layer 307 (EL) can include an organic layer.

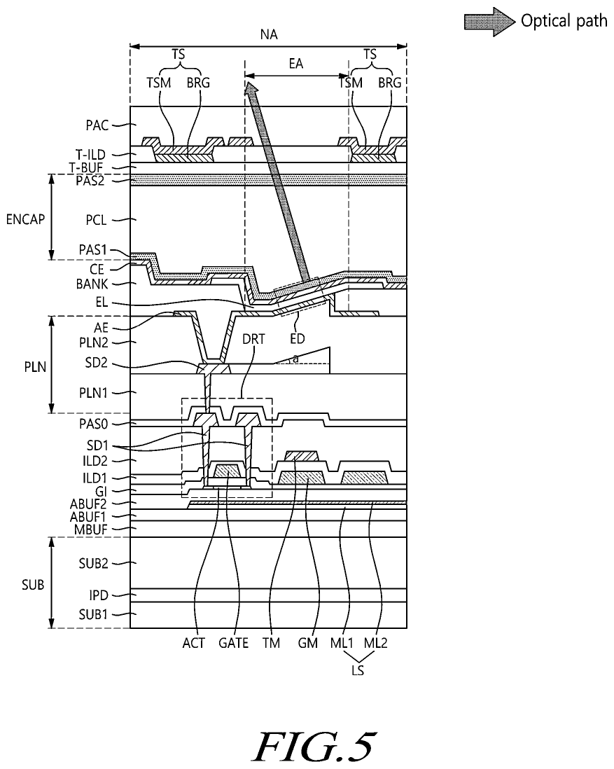

An encapsulation layer ENCAP can be disposed on the above-described light emitting device ED. The encapsulation layer ENCAP can have a single-layer structure or a multi-layer structure. For example, as shown in FIGS. 2 and 5, the encapsulation layer ENCAP can include a first encapsulation layer PAS1, a second encapsulation layer PCL and a third encapsulation layer PAS2. For example, the first encapsulation layer PAS1 and the third encapsulation layer PAS2 can be an inorganic layer, and the second encapsulation layer PCL can be an organic layer. Among the first encapsulation layer PAS1, the second encapsulation layer PCL and the third encapsulation layer PAS2, the second encapsulation layer PCL can be the thickest, and can serve as a planarization layer.

The first encapsulation layer PAS1 can be disposed on the cathode electrode CE and disposed closest to the light emitting device ED. The first encapsulation layer PAS1 can be formed of an inorganic insulating material capable of low-temperature deposition. For example, the first encapsulation layer PAS1 can be silicon nitride (SiNx), silicon oxide (SiOx), silicon oxynitride (SiON), or aluminum oxide (Al₂O₃). But embodiments of the present disclosure are not limited thereto. Since the first encapsulation layer PAS1 is deposited in a low temperature atmosphere during the deposition process, the first encapsulation layer PAS1 can prevent the damage of the light emitting layer 307 (EL) containing organic substances vulnerable to a high temperature atmosphere.

The second encapsulation layer PCL can be formed to have a smaller area than the first encapsulation layer PAS1. In this case, the second encapsulation layer PCL can be formed to expose both ends of the first encapsulation layer PAS1. The second encapsulation layer PCL can serve as a buffer to relieve stress between each layer due to bending of the display device 100, and can also serve to enhance planarization performance. For example, the second encapsulation layer PCL can be acrylic resin, epoxy resin, polyimide, polyethylene, or silicon oxycarbon (SiOC), and can be formed of an organic insulating material. But embodiments of the present disclosure are not limited thereto. For example, the second encapsulation layer PCL can be formed using an inkjet method. But embodiments of the present disclosure are not limited thereto.

The third inorganic encapsulation layer PAS2 can be formed to cover the upper surface and the side surface of the second encapsulation layer PCL and the first encapsulation layer PAS1 on the substrate SUB on which the second encapsulation layer PCL is formed. The third encapsulation layer PAS2 can minimize or block external moisture or oxygen from penetrating into the first inorganic encapsulation layer PAS1 and the organic encapsulation layer PCL. For example, the third encapsulation layer PAS2 can be formed of an inorganic insulating material such as silicon nitride (SiNx), silicon oxide (SiOx), silicon oxynitride (SiON), or aluminum oxide (Al₂O₃). But embodiments of the present disclosure are not limited thereto.

Referring to FIG. 2, when the touch sensor TS is a type built into the display panel 110, the touch sensor TS can be disposed on the encapsulation layer ENCAP. The touch sensor structure is described in detail as follows.

A touch buffer film T-BUF can be disposed on the encapsulation layer ENCAP. A touch sensor TS can be disposed on the touch buffer film T-BUF.

The touch sensor TS can include a touch sensor metal TSM and a bridge metal BRG located in different layers. A touch interlayer insulating film T-ILD can be disposed between the touch sensor metal TSM and the bridge metal BRG. For example, the touch sensor metal TSM can include a first touch sensor metal TSM, a second touch sensor metal TSM, and a third touch sensor metal TSM arranged adjacent to each other. If a third touch sensor metal TSM is located between the first touch sensor metal TSM and the second touch sensor metal TSM are required to be electrically connected to each other. the first touch sensor metal TSM and the second touch sensor metal TSM can be electrically connected to each other through a bridge metal BRG located on another layer. The bridge metal BRG can be insulated from the third touch sensor metal TSM by a touch interlayer insulating film T-ILD.

When the touch sensor TS is formed on the display panel 110, there can be chemicals (developer or etchant, etc.) used in the process or moisture from the outside present thereon. By placing the touch sensor TS on the touch buffer film T-BUF, it is possible to prevent chemicals or moisture from penetrating into the light emitting layer 307 (EL) containing organic materials during the manufacturing process of the touch sensor TS. Accordingly, the touch buffer film T-BUF can prevent damage to the light emitting layer 307 (EL), which is vulnerable to chemicals or moisture.

The touch buffer film T-BUF can be formed at a low temperature below a specific temperature (e.g., 100 degrees Celsius) in order to prevent damage to the light emitting layer 307 (EL) containing organic materials vulnerable to high temperatures, and can be made of an organic insulating material with a low dielectric constant of 1 to 3. For example, the touch buffer film T-BUF can be formed of an acrylic-based, epoxy-based, or siloxan-based material. As the display device 100 is bent, the encapsulation layer ENCAP can be damaged and the touch sensor metal located on the touch buffer layer T-BUF can be broken. Even if the display device 100 is bent, the touch buffer film T-BUF, which is made of an organic insulating material and has a flattening performance, can prevent damage to the encapsulation layer ENCAP and/or cracking of the metals TSM and BRG constituting the touch sensor TS.

A protection layer PAC can be disposed on the display panel 110 while covering the touch sensor TS. The protection layer PAC can be an organic insulating film. But embodiments of the present disclosure are not limited thereto.

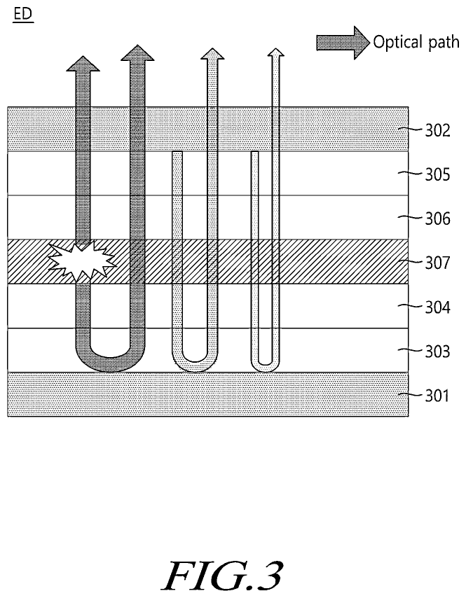

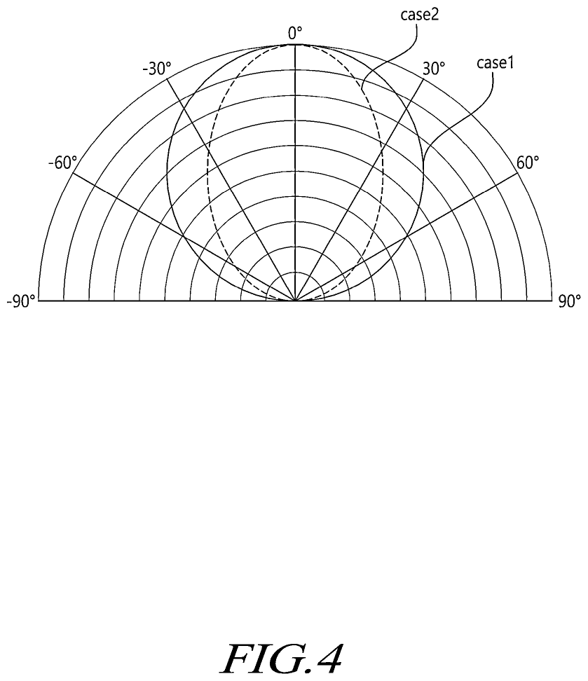

FIG. 3 is a cross-sectional view of a light emitting device ED according to embodiments of the present disclosure. FIG. 4 is a diagram illustrating a state in which the display device 100 no longer has a Lambertian distribution for the viewing angle.

Referring to FIG. 3, the light emitting device ED can include an anode 301, a hole injection layer 303 disposed on the anode 301, a hole transport layer 304 disposed on the hole injection layer 303, a light emitting layer 307 disposed on the hole transport layer 304, an electron transport layer 306 disposed on the light emitting layer 307, an electron injection layer 305 disposed on the electron transport layer 306, and a cathode 302 disposed on the electron injection layer 305.

Light emitted from the light emitting layer 307 can pass through various components of the display device 100, and come out of the display device 100. However, among the light emitted from the light emitting layer 307, there can be light that does not come out of the display device 100 and is trapped inside the display device 100. In this case, since there is an interface with a different refractive index on the light emitting surface of the light emitting device ED, there can occur a reflection, an absorption, a scattering and/or a refraction, which can lower the light efficiency and cause a light efficiency problem on the front and the side of the display device 100.

In order to solve this problem of light efficiency, there can be used a method of increasing light efficiency by creating a strong microcavity effect within the light emitting device ED by varying the thickness and refractive index of the components placed in the light emitting device ED or adding a light emitting layer 307. However, referring to FIG. 4, when the thickness and refractive index of the light emitting layer 307 are varied or other components are modified to cause the strong microcavity effect, the microcavity effect becomes stronger, so that the color of the light emitted can change depending on the viewing angle, and may not have a Lambertian distribution like case 2 in FIG. 4 due to the straight characteristic of the emitted light in contrast to the Lambertian distribution like case 1. Here, strong microcavity can refer to a state that increases the intensity of light while narrowing the half width of the main peak wavelength. A manner using the strong microcavity can improve frontal light efficiency and color purity, but there can be a trade-off relationship in which light efficiency at the viewing angle decreases and color change occurs significantly depending on the viewing angle.

Accordingly, embodiments of the present disclosure can provide a display device with a wider viewing angle that can address the above noted issues.

Embodiments of the present disclosure can provide a display device capable of increasing frontal luminance.

Embodiments of the present disclosure can provide a display device capable of low power consumption by improving the viewing angle characteristics. This will be explained in detail below.

FIG. 5 is a cross-sectional view of a light emitting area in a display panel area according to embodiments of the present disclosure.

The display device 100 can include a substrate SUB, a tilt electrode SD2 disposed on the substrate SUB to have a tilting slope on the upper surface, an anode electrode AE disposed to overlap the tilt electrode SD2, a light emitting layer 307 disposed to overlap the anode electrode AE, and a cathode electrode CE disposed to overlap the light emitting layer 307.

The display device 100 can further include an organic film planarization layer PLN2 disposed between the tilt electrode SD2 and the anode electrode AE and including a contact hole. The tilt electrode SD2 can contact the anode electrode AE through a contact hole in the organic film planarization layer PLN2.

The display device 100 can further include a driving transistor DRT disposed between the substrate SUB and the tilt electrode SD2, and the tilt electrode SD2 can be a pattern electrically connected to the driving transistor DRT.

The second source-drain electrode can be disposed on a first planarization layer PLN1. The second source drain electrode can be referred to as atilt electrode SD2. The second source-drain electrode SD2 can be the tilt electrode SD2 in various embodiments of the present disclosure.

An area corresponding to the light emitting area EA of the tilt electrode SD2 can be arranged to have a constant tilting slope (or an angle) ‘a’, where ‘a’ can be an angle between 1 degree and 70 degrees. But embodiments of the present disclosure are not limited thereto, and an angle greater than 70 degrees but less than 90 degrees is also possible. In embodiments of the present disclosure, the tilting slope (or angle) ‘a’ can be measured relative to an upper surface of the tilt electrode SD2 or the upper surface of the first planarization layer PLN1. Each of the upper surface of the tilt electrode SD2 and the upper surface of the first planarization layer PLN1 can be planar, substantially flat, or have a substantially flat portion.

The second planarization layer PLN2 can be disposed to have a slope less than or equal to the tilting slope in the area overlapping with the tilt electrode SD2, and the anode electrode AE can be disposed to have a slope less than or equal to the tilting slope in the area overlapping with the tilt electrode SD2. The light emitting layer 307 can be arranged to have a slope less than or equal to the tilting slope in the area overlapping with the tilt electrode SD2, and the cathode electrode CE can be disposed to have a slope less than or equal to the tilting slope in the overlapping area with the tilt electrode SD2.

The bank BANK can be disposed while covering a portion of the anode electrode AE. A portion of the bank BANK corresponding to the light emitting area EA of the subpixel can be open.

The bank BANK can be disposed between the anode electrode AE and the light emitting layer 307.

A portion of the anode electrode AE can be exposed through the opening (i.e., open portion) of the bank BANK. The light emitting layer 307 can be located on the side of the bank BANK and the opening (i.e., open portion) of the bank BANK. All or part of the light emitting layer 307 can be located between adjacent banks BANK.

A portion of the anode electrode AE can be exposed through the opening of the bank BANK. The opening can be an open portion of the bank BANK.

Light generated in the light emitting layer 307 can be emitted in the direction of the cathode electrode CE.

At the opening of the bank BANK, the light emitting layer 307 can be in contact with the anode electrode AE, and can be disposed to have a slope less than or equal to the tilting slope of the angle “a” in the area corresponding to the light emitting area EA.

The cathode electrode CE can be disposed on the light emitting layer 307. A portion of the cathode electrode CE corresponding to the light emitting area EA can be disposed to have a slope equal to or less than the tilting slope.

The light emitting device ED can be disposed by the anode electrode AE, the light emitting layer 307, and the cathode electrode ED. The light emitting layer 307 can include an organic layer. In addition, the anode electrode AE, the light emitting layer 307 and the cathode electrode CE can be disposed to have a slope less than or equal to the tilting slope.

The touch sensor TS can include a metal structure, and the metal structure can be in the form of a mesh-shape. The mesh-shaped metal structure can be arranged to overlap a bank around the light emitting area where light is emitted from the light emitting layer 307.

An encapsulation layer ENCAP can be disposed on the above-described light emitting device ED. The encapsulation layer ENCAP can have a single-layer structure or a multi-layer structure. For example, as shown in FIG. 5, the encapsulation layer ENCAP can include a first encapsulation layer PAS1, a second encapsulation layer PCL, and a third encapsulation layer PAS2. For example, the first encapsulation layer PAS1 and the third encapsulation layer PAS2 can be an inorganic layer, and the second encapsulation layer PCL can be an organic layer. Among the first encapsulation layer PAS1, the second encapsulation layer PCL and the third encapsulation layer PAS2, the second encapsulation layer PCL can be the thickest and can serve as a planarization layer. But embodiments of the present disclosure are not limited thereto, and at least one of the first encapsulation layer PAS1 and the third encapsulation layer PAS2 can be thicker than the second encapsulation layer PCL and serve as the planarization layer.

The structure in which the second planarization layer PLN2, anode electrode AE, light emitting layer 307, and cathode electrode CE are arranged to have a slope ‘a’ from the tilt electrode SD2 can be flattened to an original state without the tilt in the corresponding encapsulation layer ENCAP.

The light emitting layer 307 can be arranged to have a slope ‘a’ from the tilt electrode SD2. Accordingly, the direction of light emission can be tilted by the slope ‘a’. When the direction of light emission was vertical, there can occur a problem of luminance degradation due to the micro-cavity effect. As the direction of light emission is inclined by the slope ‘a’, the problem of front luminance degradation due to the micro cavity need not occur. Additionally, as the direction of light emission is tilted by the slope ‘a’, the viewing angle can be widened.

The substrate SUB can include a normal subpixel and an inclined subpixel.

The tilt electrode SD2 of the normal subpixel can be arranged to be flat.

The tilt electrode SD2 of the inclined subpixel can be arranged to have a tilting slope equal to or less than ‘a’. But embodiments of the present disclosure are not limited thereto, and the tilt electrode SD2 of the inclined subpixel can have the tilting slope greater than ‘a’.

The inclined subpixel can be arranged alternately with the normal subpixel. But embodiments of the present disclosure are not limited thereto. For example, a series of the inclined subpixels can be arranged before one or more normal pixels are arranged or vice-versa.

Each opening of the normal subpixel can vertically overlap with the light emitting area NA.

Each opening of the inclined subpixel can vertically overlap with a portion of the light emitting area, or can overlap with a portion of a bank BANK.

Additionally, with reference to FIG. 5, the tilt electrode SD2 of the inclined subpixel can have a single tilting slope that is equal to or different from ‘a’, but embodiments of the present disclosure are not limited thereto. For example, the tilt electrode SD2 can have two or more slopes (or angles) that are different from each other. For example, in addition to the slope (or angle) ‘a’, the tilt electrode SD2 can have another slope (or another angle) that is different from the slope (or angle) ‘a’. When two or more slopes are provided, a subsequent slope can be equal to or less than a previous slope, but such is not necessary, and the subsequent slope can be equal to or greater than the previous slope. Also, the slope (angle) of the tilt electrode SD2 need not be constant In other embodiments of the present disclosure, the surface of the tilt electrode SD2 can be curved so that a curvature of the tilt electrode SD2 is convex towards the encapsulation layer ENCAP. When three or more slopes are provided, a first slope, a second slope and a third slope can be provided in series. In such an instance, the second slope can be less than the first slope and the third slope can be greater than the second slope, or both the second slope and the third slope can be less than the first slope, or the third slope can be less than the second slope but can be the same as the first slope, but embodiments of the present disclosure are not limited thereto.

The tilt electrode SD2 can include a step portion at an end, and can further include a flat portion that extends from the step portion. A protruding portion of the second planarization layer PLN2 can be located at the step portion of the tilt electrode SD2.

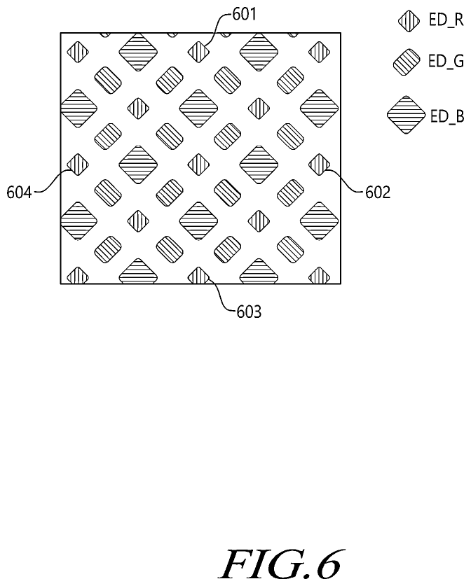

FIG. 6 is a layout diagram of subpixels SP according to embodiments of the present disclosure.

Referring to FIG. 6, the plurality of subpixels can include a plurality of red subpixels, a plurality of blue subpixels, and a plurality of green subpixels.

The plurality of red subpixels can include a first red subpixel 601, a second red subpixel 602, a third red subpixel 603, and a fourth red subpixel 604.

The plurality of subpixels can include a normal subpixel and an inclined subpixel.

Each of the first red subpixel 601, the second red subpixel 602, the third red subpixel 603, and the fourth red subpixel 604 can be disposed so as for the tilt electrode SD2 to have a tilting slope as ‘a’. But embodiments of the present disclosure are not limited thereto, and the first red subpixel 601, the second red subpixel 602, the third red subpixel 603, and the fourth red subpixel 604 can be disposed so as for the tilt electrode SD2 to have a tilting slope different from ‘a’, such as greater than ‘a’ or less than ‘a’.

In a normal red subpixel, the slope electrode SD2 can be disposed flat.

A normal red subpixel can be disposed between the first red subpixel 601, the second red subpixel 602, the third red subpixel 603, and the fourth red subpixel 604.

For example, one of the normal red subpixels can be disposed between the first red subpixel 601 and the second red subpixel 602.

For example, one of the normal red subpixels can be disposed between the second red subpixel 602 and the third red subpixel 603.

For example, one of the normal red subpixels can be disposed between the third red subpixel 603 and the fourth red subpixel 604.

For example, one of the normal red subpixels can be disposed between the fourth red subpixel 604 and the first red subpixel 601.

For example, one of the normal red subpixels can be disposed between the second red subpixel 602 and the fourth red subpixel 604.

For example, one of the normal red subpixels can be disposed between the first red subpixel 601 and the third red subpixel 603.

The first red subpixel 601 can be disposed as an inclined subpixel in which the tilt electrode SD2 of the first red subpixel 601 has a slope equal to ‘a’ in the upward direction in order for a direction of light output to directed toward the top based on the front of the display panel 110.

The second red subpixel 602 can be disposed as an inclined subpixel in which the tilt electrode SD2 of the second red subpixel 602 has a slope equal to ‘a’ in the right direction in order for a direction of light output to directed toward the right based on the front of the display panel 110.

The third red subpixel 603 can be disposed as an inclined subpixel in which the tilt electrode SD2 of the third red subpixel 603 has a slope equal to ‘a’ in the downward direction in order for a direction of light output to directed toward the bottom based on the front of the display panel 110.

The fourth red subpixel 604 can be disposed as an inclined subpixel in which the tilt electrode SD2 of the fourth red subpixel 604 has a slope equal to ‘a’ in the left direction in order for a direction of light output to directed toward the left based on the front of the display panel 110.

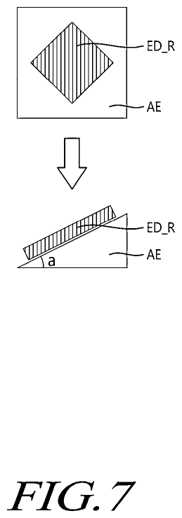

FIG. 7 is a diagram illustrating a red subpixel according to embodiments of the present disclosure.

Referring to FIG. 7, in the first red subpixel 601, the second red subpixel 602, the third red subpixel 603, and the fourth red subpixel 604, a red light emitting device ED_R can be disposed on the anode electrode AE, and the anode electrode AE can be disposed to have a slope less than or equal to the tilting slope having an angle a.

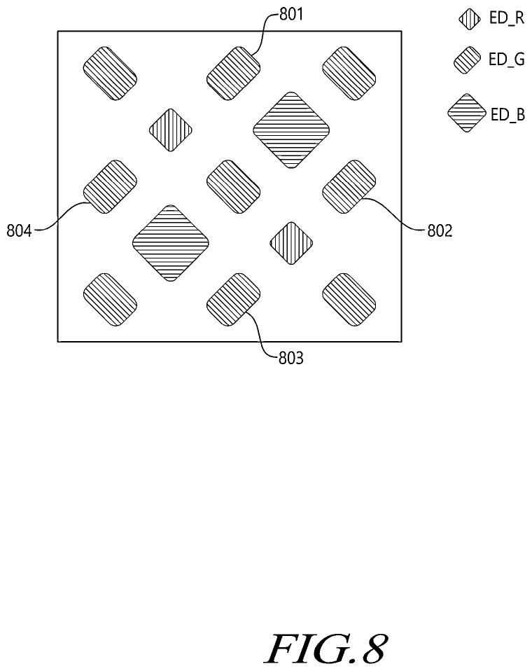

FIG. 8 is a layout diagram of subpixels SP according to embodiments of the present disclosure.

Referring to FIG. 8, the plurality of subpixels can include a plurality of red subpixels, a plurality of blue subpixels, and a plurality of green subpixels.

The plurality of green subpixels can include a first green subpixel 801, a second green subpixel 802, a third green subpixel 803, and a fourth green subpixel 804.

The plurality of subpixels can include a normal subpixel and an inclined subpixel.

Each of the first green subpixel 801, the second green subpixel 802, the third green subpixel 803, and the fourth green subpixel 804 can be disposed so as for the tilt electrode SD2 to have a tilting slope as ‘a’.

In a normal green subpixel, the slope electrode SD2 can be disposed to be flat.

A normal green subpixel can be disposed between the first green subpixel 801, the second green subpixel 802, the third green subpixel 803, and the fourth green subpixel 804.

For example, one of the normal green subpixels can be disposed between the first green subpixel 801 and the second green subpixel 802.

For example, one of the normal green subpixels can be disposed between the second green subpixel 802 and the third green subpixel 803.

For example, one of the normal green subpixels can be disposed between the third green subpixel 803 and the fourth green subpixel 804.

For example, one of the normal green subpixels can be disposed between the fourth green subpixel 804 and the first green subpixel 801.

For example, one of the normal green subpixels can be disposed between the second green subpixel 802 and the fourth green subpixel 804.

For example, one of the normal green subpixels can be disposed between the first green subpixel 801 and the third green subpixel 803.

The first green subpixel 801 can be disposed as an inclined subpixel in which the tilt electrode SD2 of the first green subpixel 801 has a slope equal to ‘a’ in the upward direction in order for a direction of light output to directed toward the top based on the front of the display panel 110.

The second green subpixel 802 can be disposed as an inclined subpixel in which the tilt electrode SD2 of the second green subpixel 802 has a slope equal to ‘a’ in the right direction in order for a direction of light output to directed toward the right based on the front of the display panel 110.

The third green subpixel 803 can be disposed as an inclined subpixel in which the tilt electrode SD2 of the third green subpixel 803 has a slope equal to ‘a’ in the downward direction in order for a direction of light output to directed toward the bottom based on the front of the display panel 110.

The fourth green subpixel 804 can be disposed as an inclined subpixel in which the tilt electrode SD2 of the fourth green subpixel 804 has a slope equal to ‘a’ in the left direction in order for a direction of light output to directed toward the left based on the front of the display panel 110.

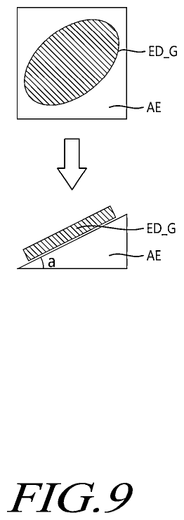

FIG. 9 is a diagram illustrating a green subpixel according to embodiments of the present disclosure.

Referring to FIG. 9, in the first green subpixel 801, the second green subpixel 802, the third green subpixel 803, and the fourth green subpixel 804, a green light emitting device ED_G can be disposed on the anode electrode AE, and the anode electrode AE can be disposed to have a slope less than or equal to the tilting slope with an angle a.

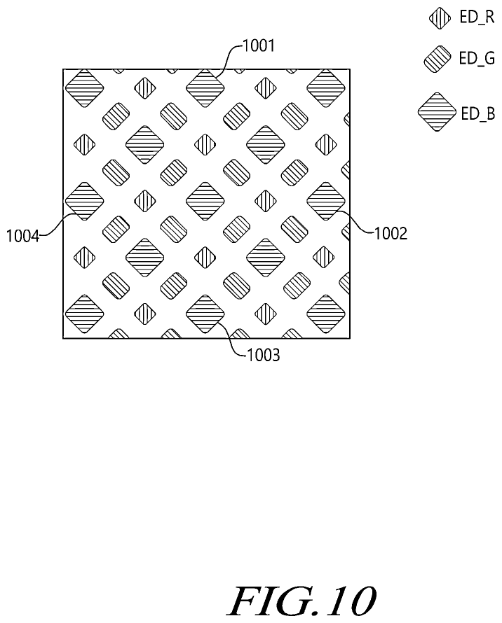

FIG. 10 is a layout diagram of subpixels SP according to embodiments of the present disclosure.

Referring to FIG. 10, the plurality of subpixels can include a plurality of red subpixels, a plurality of blue subpixels, and a plurality of green subpixels.

The plurality of blue subpixels can include a first blue subpixel 1001, a second blue subpixel 1002, a third blue subpixel 1003, and a fourth blue subpixel 1004.

The plurality of subpixels can include a normal subpixel and an inclined subpixel.

Each of the first blue subpixel 1001, the second blue subpixel 1002, the third blue subpixel 1003, and the fourth blue subpixel 1004 can be disposed so as for the tilt electrode SD2 to have a tilting slope as ‘a’.

In a normal blue subpixel, the slope electrode SD2 can be disposed flat.

A normal blue subpixel can be disposed between the first blue subpixel 1001, the second blue subpixel 1002, the third blue subpixel 1003, and the fourth blue subpixel 1004.

For example, one of the normal blue subpixels can be disposed between the first blue subpixel 1001 and the second blue subpixel 1002.

For example, one of the normal blue subpixels can be disposed between the second blue subpixel 1002 and the third blue subpixel 1003.

For example, one of the normal blue subpixels can be disposed between the third blue subpixel 1003 and the fourth blue subpixel 1004.

For example, one of the normal blue subpixels can be disposed between the fourth blue subpixel 1004 and the first blue subpixel 1001.

For example, one of the normal blue subpixels can be disposed between the second blue subpixel 1002 and the fourth blue subpixel 1004.

For example, one of the normal blue subpixels can be disposed between the first blue subpixel 1001 and the third blue subpixel 1003.

The first blue subpixel 1001 can be disposed as an inclined subpixel in which the tilt electrode SD2 of the first blue subpixel 1001 has a slope equal to ‘a’ in the upward direction in order for a direction of light output to directed toward the top based on the front of the display panel 110.

The second blue subpixel 1002 can be disposed as an inclined subpixel in which the tilt electrode SD2 of the second blue subpixel 1002 has a slope equal to ‘a’ in the right direction in order for a direction of light output to directed toward the right based on the front of the display panel 110.

The third blue subpixel 1003 can be disposed as an inclined subpixel in which the tilt electrode SD2 of the third blue subpixel 1003 has a slope equal to ‘a’ in the downward direction in order for a direction of light output to directed toward the bottom based on the front of the display panel 110.

The fourth blue subpixel 1004 can be disposed as an inclined subpixel in which the tilt electrode SD2 of the fourth blue subpixel 1004 has a slope equal to ‘a’ in the left direction in order for a direction of light output to directed toward the left based on the front of the display panel 110.

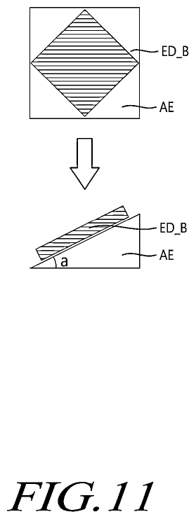

FIG. 11 is a diagram illustrating a blue subpixel according to embodiments of the present disclosure.

Referring to FIG. 11, in the first blue subpixel 1001, the second blue subpixel 1002, the third blue subpixel 1003, and the fourth blue subpixel 1004, a blue light emitting device ED_B can be disposed on the anode electrode AE, and the anode electrode AE can be disposed to have a slope less than or equal to the tilting slope having an angle a.

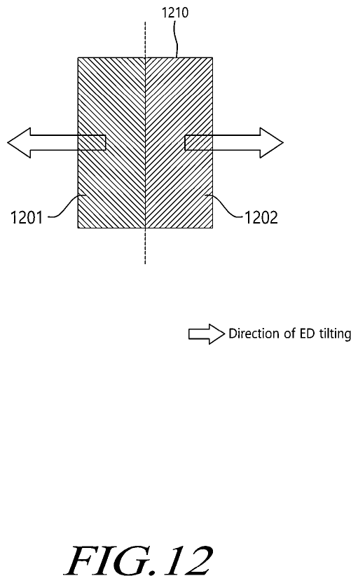

FIG. 12 is a diagram of a display panel 1210 having the divided areas according to embodiments of the present disclosure.

Referring to FIG. 12, the substrate SUB of the display panel 1210 can be divided into a left area (or a first area) 1201 and a right area (or a second area) 1202. Alternatively, the substrate SUB of the display panel 1210 can be divided into an upper area and a lower area. For example, the substrate SUB of the display panel 1210 can include a first area and a second area that are tilted in opposite directions. But embodiments of the present disclosure are not limited thereto.

The light emitting layer 307 included in the inclined subpixel of the left area 1201 can be disposed to be inclined toward the left. As the light emitting layer 307 included in the inclined subpixel of the left area 1201 is arranged to be tilted to the left, there can be widened the viewing angle in the left direction of the display panel 1210.

The light emitting layer 307 included in the inclined subpixel of the right area 1202 can be arranged to be inclined toward the right. As the light emitting layer 307 included in the inclined subpixel of the right area 1202 is disposed to be tilted to the right, there can be widened the viewing angle in the right direction of the display panel 1210.

A virtual reference line dividing the left area 1201 and the right area 1202 of the display panel 1210 can be a center line which vertically crosses the display panel 1210, and the display panel 1210 can be divided into a left area 1201 and a right area 1202 based on the corresponding center line.

A virtual reference line dividing the upper and lower areas of the display panel 1210 can be a center line crossing the display panel 1210 in the horizontal direction, and the display panel 1210 can be divided into the upper area and the lower area based on the center line in other embodiments of the present disclosure.

With reference to FIG. 12, in addition to the left area 1201 and the right area 1202, the display panel 1210 can further have a third area between the left area 1201 and the right area 1202. The third area can be an area having a different slope from those of the left area 1201 and the right area 1202. In various embodiments of the present disclosure, the third area can be an area that is flat or planar, or an area having a slope that is less than those of the left area 1201 and the right area 1202. But embodiments of the present disclosure are not limited thereto.

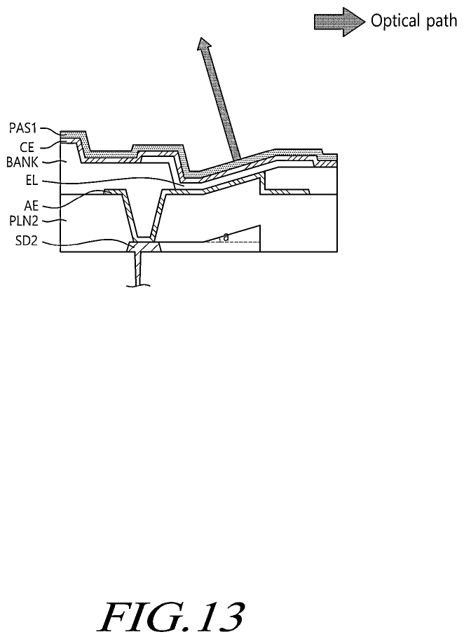

FIG. 13 is a cross-sectional view of a light emitting area in a left area 1201 of the display panel 1210 of FIG. 12 according to embodiments of the present disclosure.

Referring to FIG. 13, at least some subpixels included in the left area 1201 can be disposed so that, from the tilt electrode SD2, the second planarization layer PLN2 disposed on the tilt electrode SD2, the anode electrode AE disposed on the second planarization layer PLN2, the light emitting layer 307 disposed on the anode electrode AE, and the cathode electrode CE disposed on the light emitting layer 307 have a slope less than or equal to the tilting slope to the left.

Referring to FIG. 13, when the display panel 110 is divided into a left area 1201 and a right area 1202, there can be an inclined subpixel disposed in the left area 1201 of the substrate SUB.

The tilt electrode SD2 included in the inclined subpixel can be disposed to have a tilting slope. The anode electrode AE can be arranged to have a slope less than or equal to the tilting slope on the tilt electrode SD2. The light emitting layer 307 can be disposed to have a slope less than or equal to the tilting slope on the anode electrode AE. The cathode electrode CE can be disposed on the light emitting layer 307 to have a slope equal to or less than the tilting slope.

Since the light emitting layer 307 is arranged to have a slope equal to or less than the predetermined tilting slope, the direction of light emitted from the light emitting layer 307 can be toward the left rather than the front. For example, the viewing angle can be widened in the left area 1201 of the display panel 110.

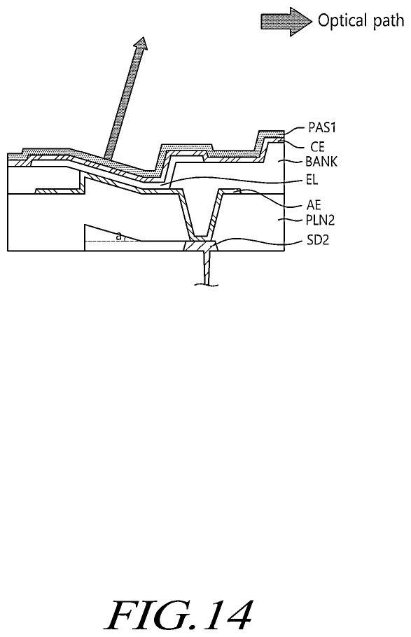

FIG. 14 is a cross-sectional view of a light emitting area in a right area 1202 of the display panel 1201 of FIG. 12 according to embodiments of the present disclosure.

Referring to FIG. 14, at least some subpixels included in the right area 1202 can be disposed so that, from the tilt electrode SD2, the second planarization layer PLN2 disposed on the tilt electrode SD2, the anode electrode AE disposed on the second planarization layer PLN2, the light emitting layer 307 disposed on the anode electrode AE, and the cathode electrode CE disposed on the light emitting layer 307 have a slope less than or equal to the tilting slope to the right.

As shown in FIGS. 12, 13 and 14, an effect of widening the left and right viewing angles by arranging the subpixels in different tilt directions according to the left area 1201 and the right area 1202 can be provided in the display panel 1210.

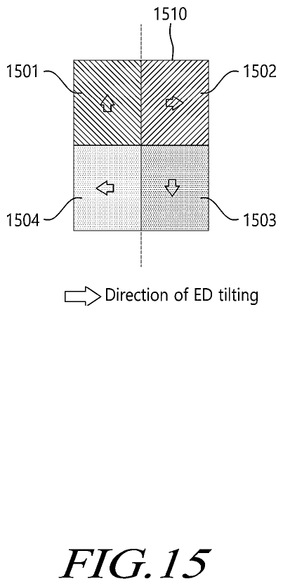

FIG. 15 is a cross-sectional view of light emitting areas of a display panel 1510 divided into areas according to embodiments of the present disclosure.

Referring to FIG. 15, the substrate SUB of the display panel 1510 can include a first area 1501, a second area 1502, a third area 1503 and a fourth area 1504.

The light emitting layer 307 included in the inclined subpixel of the first area 1501 can be arranged to be inclined in a first direction, for example, upward. As the light emitting layer 307 included in the inclined subpixel of the first area 1501 is disposed to be inclined upward, the viewing angle toward the top of the display panel 1510 can be widened.

The light emitting layer 307 included in the inclined subpixel of the second area 1502 can be arranged to be inclined in a second direction, for example, to the right. As the light emitting layer 307 included in the inclined subpixel of the second area 1502 is disposed to be inclined to the right, the viewing angle in the right direction of the display panel 1510 can be widened.

The light emitting layer 307 included in the inclined subpixel of the third area 1503 can be arranged to be inclined in a third direction, for example, downward. As the light emitting layer 307 included in the inclined subpixel of the third area 1503 is disposed to be inclined downward, the viewing angle in the downward direction of the display panel 1510 can be widened.

The light emitting layer 307 included in the inclined subpixel of the fourth area 1504 can be arranged to be inclined in a fourth direction, for example, to the left. As the light emitting layer 307 included in the inclined subpixel of the fourth area 1504 is disposed to be inclined to the left, the viewing angle in the left direction of the display panel 1510 can be widened.

In addition, the display panel 1510 can be divided into more detailed areas to provide an improved viewing angle depending on the user's usage environment.

With reference to FIG. 15, in addition to the first area 1501, the second area 1502, the third area 1503 and the fourth area 1504, the display panel 1510 can further have a fifth area between any two of the first area 1501, the second area 1502, the third area 1503 and the fourth area 1504, or all of the first area 1501, the second area 1502, the third area 1503 and the fourth area 1504. The fifth area can be an area having a slope that is different or the same as those of the first area 1501, the second area 1502, the third area 1503 and the fourth area 1504. In various embodiments of the present disclosure, the fifth area can be an area that is flat or planar, or an area having a slope that is equal to or less than those of at least one of the first area 1501, the second area 1502, the third area 1503 and the fourth area 1504. But embodiments of the present disclosure are not limited thereto.

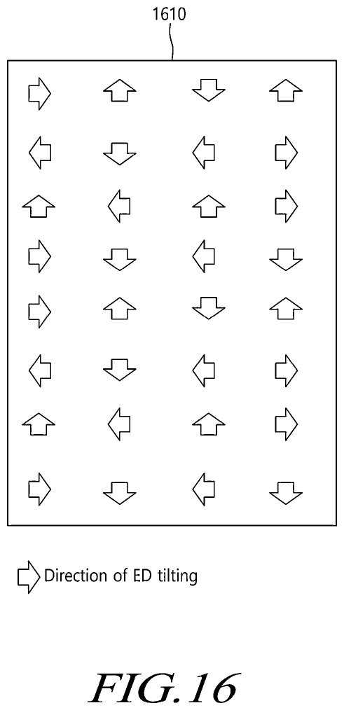

FIG. 16 is a diagram of a display panel 1610 according to embodiments of the present disclosure.

The display panel 1610 can include inclined subpixels arranged so that each light emitting layer 307 is inclined by an amount of ‘a’ in a random direction in some or all areas.

In at least some subpixels of the display panel 1610, each light emitting layer 307 is arranged to be inclined by ‘a’ in a random direction, so that the viewing angle can be uniformly widened.

The subpixel including the light emitting layer 307 inclined by ‘a’ can be arranged differently depending on the type of display panel 110.

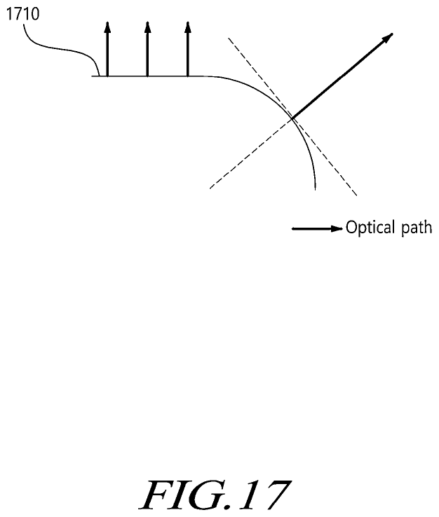

FIG. 17 is a diagram of an edge area of a display panel 1710 according to embodiments of the present disclosure.

The display panel 1710 shown in FIG. 17 can be a display panel 1710 whose edge area is curved by applying curvature to the edge area.

In the display panel 1710, the direction of light can leak to the side in the corner area where the curvature is applied, so that the luminance recognized by the user in front can reduced.

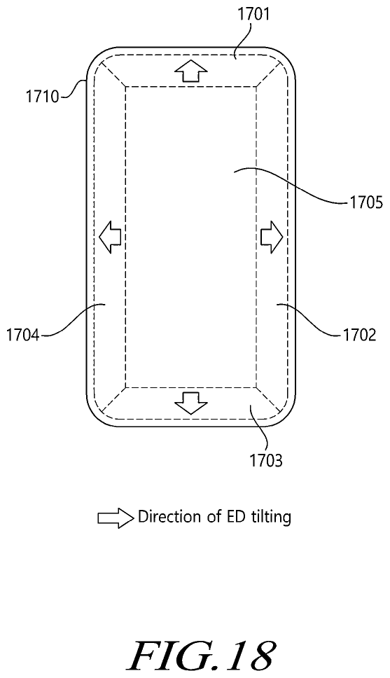

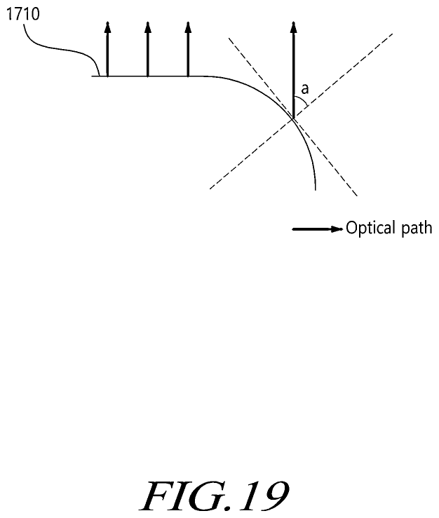

FIGS. 18 and 19 are diagrams of edge areas of a display panel 1710 according to embodiments of the present disclosure.

The display panel 1710 can include a flat area 1705 and an edge area which is an outer area of the flat area 1705. The light emitting layer 307 of the inclined subpixel disposed in the edge area can be disposed to have a slope less than or equal to the tilting slope.

The substrate of the display panel 1710 can include a flat area 1705 and an edge area as an outer area of the flat area 1705. The light emitting layer 307 of the inclined subpixel disposed in the edge area can be disposed to have a slope less than or equal to the tilting slope.

Referring to FIGS. 18 and 19, the display panel 1710 can include an edge area disposed at a corner of a flat area 1705 having no curvature. The display panel 1710 can be curved by applying curvature to the edge area of the corner portion.

The display panel 1710 can include a first edge area 1701 which is an upper edge area, a second edge area 1702 which is a right edge area, a third edge area 1703 which is a lower edge area, and a fourth edge area 1704 which is a left edge area.

The light emitting layer 307 included in the inclined subpixel of the first edge area 1701 of the display panel 1710 can be arranged to be inclined in a first direction. As the light emitting layer 307 included in the inclined subpixel of the first edge area 1701 is arranged to be inclined in the first direction, there can be improved a visibility for a user located in front of the display panel 1710.

The light emitting layer 307 included in the inclined subpixel of the second edge area 1702 of the display panel 1710 can be arranged to be inclined in a second direction. As the light emitting layer 307 included in the inclined subpixel of the second edge area 1702 is arranged to be inclined in the second direction, there can be improved a visibility for a user located in front of the display panel 1710.

The light emitting layer 307 included in the inclined subpixel of the third edge area 1703 of the display panel 1710 can be arranged to be inclined in a third direction. As the light emitting layer 307 included in the inclined subpixel of the third edge area 1703 is arranged to be inclined in the third direction, there can be improved a visibility for a user located in front of the display panel 1710.

The light emitting layer 307 included in the inclined subpixel of the fourth edge area 1704 of the display panel 1710 can be arranged to be inclined in a fourth direction, for example, to the left. As the light emitting layer 307 included in the inclined subpixel of the fourth edge area 1704 is arranged to be inclined in the fourth direction, there can be improved a visibility for a user located in front of the display panel 1710.

The substrate SUB of the display panel 2010 can have a specific curvature. A normal subpixel can be disposed in the center of the substrate SUB. An inclined subpixel can be disposed in an area other than the center of the substrate SUB.

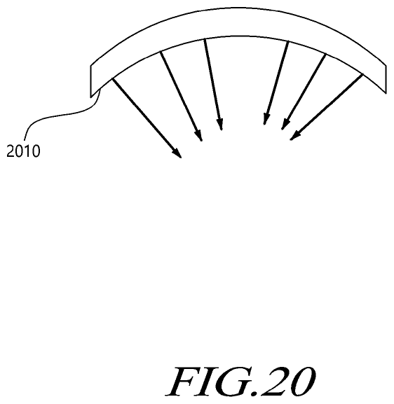

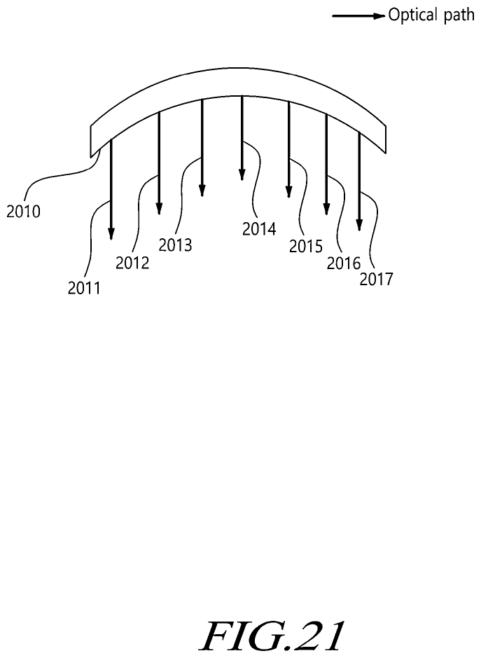

FIGS. 20 and 21 are diagrams of display panels 2010 according to embodiments of the present disclosure.

In the case of a curved display panel 2010 in which curvature is applied throughout the entire area of the display panel 2010, since the display panel 2010 is curved, the direction of light coming from the subpixels can be concentrated at one point, which can cause a difficulty in securing a wide viewing angle.

An inclined subpixel can be disposed in an area other than the center of the display panel 2010 shown in FIG. 21. The slope of the inclined subpixel can be set so that the direction of light emitted from the curved display panel 2010 is parallel, thereby securing a wide viewing angle of the display panel 2010. For example, optical paths 2011, 2012, 2013, 2014, 2015, 2016 and 2017 can be generated based on respective angles of the tilt electrodes SD2 that are provided, and the respective angles of the tilt electrodes SD2 of the optical paths 2011, 2012, 2013, 2014, 2015, 2016 and 2017 can be respectively adjusted and same or different with each other to provide parallel beams of light or optical paths.

Embodiments of the present disclosure described above are briefly described as follows.

A display device according to embodiments of the present disclosure can include a substrate, a tilt electrode disposed on the substrate and disposed to have an upper surface of a tilting slope, a pixel electrode disposed to overlap the tilt electrode, a light emitting layer disposed to overlap the pixel electrode, and a cathode electrode disposed to overlap the light emitting layer.

The display device according to embodiments of the present disclosure can further include an organic film planarization layer disposed between the tilt electrode and the pixel electrode and including a contact hole, and the tilt electrode can contact the pixel electrode through the contact hole in the organic film planarization layer.

The display device according to embodiments of the present disclosure can further include a driving transistor disposed between the substrate and the tilt electrode, and the tilt electrode can be an electrode included in the driving transistor or a pattern electrically connected to the driving transistor.

The organic film planarization layer can be disposed to have a slope less than or equal to the tilting slope in an area overlapping with the tilt electrode, the pixel electrode can be disposed to have a slope less than or equal to the tilting slope in an area overlapping with the tilt electrode, the light emitting layer can be disposed to have a slope less than or equal to the tilting slope in an area overlapping with the tilt electrode, and the cathode electrode can be disposed to have a slope less than or equal to the tilting slope in an area overlapping with the tilt electrode.

Light generated in the light emitting layer can be emitted in a direction of the cathode electrode.

The tilting slope can be 1 degree to 70 degrees.

The substrate can include a normal subpixel and an inclined subpixel. a tilt electrode of the normal subpixel can be arranged to be flat, and a tilt electrode of the inclined subpixel can be disposed to have an upper surface of the tilting slope.

The inclined subpixel can be disposed alternately with the normal subpixel.

The substrate can include a left area and a right area. A light emitting layer included in the inclined subpixel of the left area can be disposed to be inclined to the left, and a light emitting layer included in the inclined subpixel of the right area can be disposed to be inclined to the right.

The substrate can include a first area, a second area, a third area and a fourth area. A light emitting layer included in the inclined subpixel of the first area can be disposed to be inclined to a first direction, a light emitting layer included in the inclined subpixel of the second area can be disposed to be inclined to a second direction, a light emitting layer included in the inclined subpixel of the third area can be disposed to be inclined to a third direction, and a light emitting layer included in the inclined subpixel of the fourth area can be disposed to be inclined to a fourth direction.

The substrate can include a flat area and an edge area which is an outer area of the flat area. A light emitting layer of the inclined subpixel disposed in the edge area can be disposed to have the tilting slope.

The substrate can have a specific curvature, and the normal subpixel can be disposed in a center of the substrate, and the inclined subpixel can be disposed in an area other than the center of the substrate.

The display device according to embodiments of the present disclosure can further include a bank disposed between the light emitting layer and the pixel electrode, and a touch sensor disposed on the cathode electrode. The touch sensor can include a mesh-shaped metal structure, and the metal structure can be disposed to overlap with the bank around a light emitting area where light generated from the light emitting layer is emitted.

Each opening of the normal subpixel can vertically overlap with the light emitting area, and each opening of the inclined subpixel can vertically overlap with a portion of the light emitting area or overlaps with a portion of the bank.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a substrate;
a tilt electrode disposed on the substrate and having an upper surface of a tilting slope;
a pixel electrode disposed to overlap the tilt electrode;
a light emitting layer disposed to overlap the pixel electrode; and
a cathode electrode disposed to overlap the light emitting layer.

2. The display device of claim 1, further comprising an organic film planarization layer disposed between the tilt electrode and the pixel electrode and including a contact hole,
wherein the tilt electrode contacts the pixel electrode through the contact hole in the organic film planarization layer.

3. The display device of claim 2, further comprising a driving transistor disposed between the substrate and the tilt electrode,
wherein the tilt electrode is an electrode included in the driving transistor or a pattern electrically connected to the driving transistor.

4. The display device of claim 2, wherein the organic film planarization layer has a slope less than or equal to the tilting slope in an area overlapping with the tilt electrode,
wherein the pixel electrode has a slope less than or equal to the tilting slope in an area overlapping with the tilt electrode,
wherein the light emitting layer has a slope less than or equal to the tilting slope in an area overlapping with the tilt electrode, and
wherein the cathode electrode has a slope less than or equal to the tilting slope in an area overlapping with the tilt electrode.

5. The display device of claim 4, wherein light generated in the light emitting layer is emitted in a direction of the cathode electrode.

6. The display device of claim 1, wherein the tilting slope is approximately 1 degree to 70 degrees.

7. The display device of claim 1, wherein the substrate includes a normal subpixel and an inclined subpixel,
wherein a tilt electrode of the normal subpixel is substantially flat, and
wherein a tilt electrode of the inclined subpixel has the upper surface of the tilting slope.

8. The display device of claim 7, wherein the inclined subpixel is disposed alternately with the normal subpixel.

9. The display device of claim 7, wherein the substrate includes a first area and a second area,
wherein a light emitting layer included in the inclined subpixel of the first area is disposed to be inclined to a first direction, and a light emitting layer included in the inclined subpixel of the second area is disposed to be inclined to a second direction opposite to the first direction.

10. The display device of claim 7, wherein the substrate includes a first area, a second area, a third area and a fourth area,
wherein a light emitting layer included in the inclined subpixel of the first area is inclined in a first direction,
wherein a light emitting layer included in the inclined subpixel of the second area is inclined in a second direction,
wherein a light emitting layer included in the inclined subpixel of the third area is inclined in a third direction, and
wherein a light emitting layer included in the inclined subpixel of the fourth area is inclined in a fourth direction.

11. The display device of claim 7, wherein the substrate includes a flat area and an edge area which is adjacent to the flat area, and
wherein a light emitting layer of the inclined subpixel disposed in the edge area has the tilting slope.

12. The display device of claim 7, wherein the substrate has a curvature at a periphery thereof, and
wherein the normal subpixel is disposed in a center of the substrate, and the inclined subpixel is disposed in an area other than the center of the substrate.

13. The display device of claim 7, further comprising:
a bank disposed between the light emitting layer and the pixel electrode; and
a touch sensor disposed on the cathode electrode,
wherein the touch sensor includes a mesh-shaped metal structure, and
wherein the metal structure is disposed to overlap with the bank around a light emitting area where light generated from the light emitting layer is emitted.

14. The display device of claim 13, wherein each opening of the normal subpixel vertically overlaps with the light emitting area, and
wherein each opening of the inclined subpixel vertically overlaps with a portion of the light emitting area or overlaps with a portion of the bank.

15. The display device of claim 1, wherein the tilt electrode includes a plurality of tilting slopes, including the tilting slope.

16. The display device of claim 15, wherein the plurality of tilting slopes include a first tilting slope and a second tilting slope, and a tilt of the first tilting slope is different from a tilt of the second tilting slope.

17. The display device of claim 1, wherein the upper surface of the tilting slope is curved.

18. The display device of claim 1, where the tilt electrode includes a step portion.
